(19) United States
(12) Patent Application Publication
(10) Pub. No.: US 2023/0394217 A1
(43) Pub. Date: Dec. 7, 2023

(54) INTEGRATED CIRCUIT (IC) DESIGN METHODS USING PROCESS FRIENDLY CELL ARCHITECTURES

(71) Applicant: Taiwan Semiconductor Manufacturing Co., Ltd., Hsinchu City (TW)

(72) Inventors: Fei Fan DUAN, New Taipei City (TW); Li-Chun TIEN, Tainan City (TW); Chih-Liang CHEN, Hsinchu City (TW)

(21) Appl. No.: 17/834,606

(22) Filed: Jun. 7, 2022

(51) Int. Cl. G06F 30/398; H01L 21/768; H01L 21/027

(52) U.S. Cl. CPC G06F 30/398; H01L 21/0273; H01L 21/7687

(57) ABSTRACT

Methods and Apparatuses for making an integrated circuit (IC) are disclosed. In accordance with some embodiments, a method including forming one or more decoupling capacitor (DCAP) cells comprising one or more polysilicon (PO) layers openings formed based on one or more photoresist layer openings formed to solve one or more design rule check (DRC) violations. The one or more DCAP cells also provide decoupling capacitors for the IC.

### BACKGROUND

Integrated circuit design is the process through which the electrical components of a circuit are designed, simulated, and stored such that the integrated circuit can be formed on a semiconductor substrate. Application-specific integrated circuits (“ASICs”) are typically designed using a standard cell (or “cell”) methodology in which standard cells are developed having a particular length and width. Under the cell methodology, each cell can have a different configuration such that the cell performs a certain function, e.g., a buffer, a latch, or a logic function (e.g., AND, OR, etc.). These cells are placed to form a layout according to certain design rules, which include manufacturing constraints that set forth specific spacing requirements between adjacent cells and/or pins for input/output (“I/O”) and power.

During the design of integrated circuits, a place and route stage is performed to implement all the desired design connections while following the rules and limitations of the manufacturing process. During the place and route stage, FILL cells are used to connect power and ground rails across an area containing no cells. The FILL cells are also used to solve design rule violations in an integrated circuit layout. However, these FILL cells do not have any functionality, and implementation of these FILL cells can result in a waste of valuable chip real estate. Therefore, prior art solutions for using these FILL cells are not entirely satisfactory.

### BRIEF DESCRIPTION OF THE DRAWINGS

Aspects of the present disclosure are best understood from the following detailed description when read with the accompanying figures. It is noted that, in accordance with the standard practice in the industry, various features are not necessarily drawn to scale, and the dimensions of the various features may be arbitrarily increased or reduced for clarity of discussion.

FIG. 1 illustrates an embodiment of a decoupling capacitor (DCAP) cell in accordance with the present disclosure.

FIG. 2 illustrates an exemplary scenario of the DCAP cell used for solving design rule checking (DRC) violations in accordance with the present disclosure.

FIG. 3 illustrates an exemplary scenario schematic of a decoupling capacitor created by the decoupling capacitor cell, in accordance with some embodiments.

FIG. 4 illustrates another embodiment of the DCAP cell in accordance with the present disclosure.

FIG. 5 illustrates another exemplary scenario of the DCAP cell used for solving DRC violations in accordance with the present disclosure.

FIG. 6 illustrates still another embodiment of the DCAP cell in accordance with the present disclosure.

FIG. 7 illustrates a cross section view of the DCAP cell in accordance with the present disclosure.

FIG. 8 illustrates still another exemplary scenario of the DCAP cell used for solving DRC violations, in accordance with some embodiments.

FIG. 9 illustrates yet another embodiment of the DCAP cell in accordance with the present disclosure.

FIG. 10 illustrates another cross section view of the DCAP cell, in accordance with some embodiments.

FIG. 11 illustrates still another exemplary scenario of the DCAP cell used for solving DRC violations, in accordance with some embodiments.

FIG. 12 illustrates still another exemplary scenario of the DCAP cell used for solving DRC violations, in accordance with some embodiments.

FIG. 13 illustrates still another exemplary scenario of the DCAP cell used for solving DRC violations, in accordance with some embodiments.

FIG. 14 illustrates still another exemplary scenario of the DCAP cell used for solving DRC violations, in accordance with some embodiments.

FIG. 15 illustrates various views of an exemplary transistor in the DCAP cell used for creating the decoupling capacitor in accordance with the present disclosure.

FIG. 16A-F illustrates sequential steps of a method for forming a process-friendly DCAP cell, in accordance with some embodiments.

FIG. 17 illustrates an example method for designing an integrated circuit, in accordance with some embodiments.

FIG. 18 illustrates a simplified computer system that can be used to implement various embodiments described and illustrated herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include integrated circuit (IC) design methods using process friendly cell architectures. In particular, exemplary aspects provide one or more decoupling capacitor (DCAP) cells that are used to solve one or more design rule checking (DRC) violations on the layout of an IC. In an example embodiment, the one or more DCAP cells comprise at least one capacitor formed by an M0 metal layer and an M1 metal layer. In another embodiment, the at least one capacitor is formed by at least one p-channel metal oxide semiconductor (PMOS) transistor in the one or more DCAP cells.

Before addressing exemplary aspects of the present disclosure, a few definitions are provided to assist with acronyms that may appear in the present disclosure.

Middle-end-of-line (MEOL) may also sometimes be referred to as MOL. MEOL or MOL is generally associated with local interconnect and lower levels of metal formation.

Front-end-of-line (FEOL) is associated with transistor formation and occurs first in the manufacturing process (hence-front).

Back-end-of-line (BEOL) is generally associated with handling metals layers and vias.

Metal layers exist to allow interconnections between active elements. While the precise number of metal layers may vary, there are typically more than four (4), and perhaps more than fifteen (15) metal layers. These are referred to as M0-Mx where x is an integer one less than the number of metal layers. Thus, if there are eight (8) metal layers, these would be denoted M0-M7. M0 refers to the lowest metal layer, i.e., closest to the layer with the active elements thereon, and M7 would be the highest metal layer (generally the last metal layer created in the circuit). Some industry participants refer to the lowest metal layer as M1 instead of M0. However, such nomenclature is not used herein. Even in this alternate naming approach, the higher the number, the higher the metal layer (i.e., more removed from the substrate).

Polysilicon layers (sometimes shortened to poly or PO) are usually used to form gates for transistors and in some processes are actually metal but still referred to as poly.

Oxide diffusion layers (sometimes shortened to OD) are usually used to form an active area for a transistor, i.e., the area where the source, the drain and the channel under the gate of the transistor are located.
MD—a “metal layer” to “diffusion layer” layer. The layer is in-between the metal layer M0 and the diffusion layer.
MP—a metal-to-poly layer.
CMD—a cut MD layer.
CPO—a cut poly layer.
VD—the vias between the diffusion layer or MD and M0.
VG—the vias between the poly or MP layer and M0.
VIA0—the via between M0 and M1.

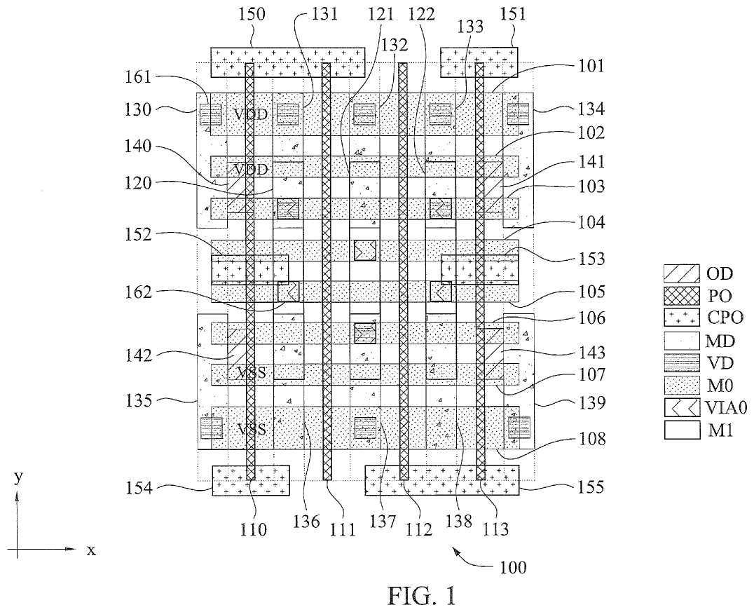

FIG. 1 illustrates an embodiment of a DCAP cell 100. The DCAP cell 100 may be rectilinearly shaped and is four (4) poly pitches wide laterally in the x-axis, in accordance with some embodiments. In some embodiments, multiple DCAP cells 100 may be coupled either in the x-axis or the y-axis dimension to allow for greater complex functions to be realized. The coupling of the DCAP cells 100 may require additional connections in the metal layers (e.g. M1 or M2). The DCAP cell 100 may include M0 tracks 101-108, running on an M0 mask layer in the x-axis direction. The M0 tracks 101 and 102 may be connected to a power line (VDD) provided by external circuitry (not shown), and the M0 tracks 107 and 108 may be connected to a ground line (VSS) provided by external circuitry (not shown).

In some embodiments, the DCAP cell 100 includes polysilicon (PO) shapes 110-113 running orthogonal to the M0 shapes in the y-axis direction, M1 tracks 120-122 running on an M1 mask layer in the y-axis, MD shapes 130-139 running on an MD mask layer in the y-axis, OD shapes 140-143 running on an OD mask layer in the y-axis. VD vias 161 provide a means to connect MD layer to M0 layer, and VIA0 vias 162 provide a means to connect M0 layer to M1 layer.

In some embodiments, the DCAP cell 100 includes cut poly (CPO) shapes 150-155 running on a CPO layer in the x-axis. The CPO shapes at the same horizontal level are disconnected to provide an isolation of the CPO shapes. For example, the CPO shape pairs 150 and 151, 152 and 153, 154 and 155, respectively, are disconnected from each other with an empty space between the two shapes.

In one example, the DCAP cell 100 is placed at one or more locations on a first circuit layout of an integrated circuit (IC) to solve one or more design rule checking (DRC) violations. A DRC violation may be referred to a violation of one or more geometric constraints imposed on an IC layout. The one or more geometric constraints may be used to ensure IC designs function properly, reliably, and can be produced with acceptable yield. Examples of the one or more geometric constraints include width rules specifying the minimum or maximum width/length of any shape in the design, spacing rules specifying the minimum distance between two adjacent objects, minimum or maximum area rules specifying the minimum or maximum area of any shape, two-layer rules specifying the relationship that must exist between two layers, and/or any other geometric constraints. In some examples, a set of DRC rules for a specific technology node may be stored in a design rule data set for further processing.

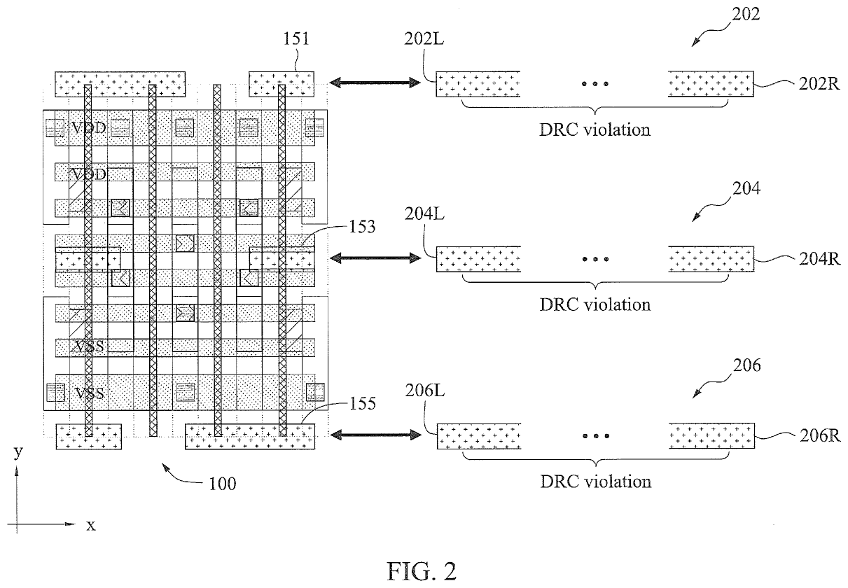

In some embodiments, the set of DRC rules comprises a maximum allowed length for CPO lines on the layout of an IC, and DRC violations comprise CPO lines with lengths greater than a first predetermined value. For example, referring to FIG. 2, each of the three CPO lines 202, 204, and 206 has a length greater than the first predetermined value for CPO lines, thus resulting in DRC violations. The set of DRC rules may then include actions performed on the layout to solve DRC violations. Still referring to FIG. 2, to solve DRC violations, the DRC rules may specify an action to make the two edges of a CPO line as floating nodes if the length of the CPO line is greater than the first predetermined value. Making two edges of a CPO line as floating nodes may be referred to as an action to disconnect the two edges from other parts of the layout. A DCAP cell 100 may be placed at the left edges 202L, 204L and 206L of the CPO lines 202, 204, and 206, respectively, such that the CPO shapes 151, 153, and 155 in the DCAP cell 100 are connected to the left edges of the CPO lines 202, 204, and 206, respectively. In the same way, another DCAP cell 100 (not shown) may be placed at the right edges 202R, 204R and 206R of the CPO lines 202, 204, and 206, respectively. In this way, since the two CPO shapes at the same horizontal level in the DCAP cell 100 are disconnected from other parts of the circuit layout, the DRC violations are solved by disconnecting the two edges of the CPO lines 202, 204, and 206 from other parts of the layout. In some examples, multiple DCAP cells 100 may be placed either laterally or vertically to solve DRC violations.

Referring back to FIG. 1, in addition to solving DRC violations, one specifically contemplated function for the DCAP cell 100 is a decoupling capacitor. A decoupling capacitor may be referred to a capacitor used to decouple one part of an IC from another part for reducing noise and bypassing a power supply or other high impedance component. Examples of decoupling capacitors in an IC include Metal-Insulator-Metal (MIM) capacitor, Metal-Oxide-Metal (MOM) capacitor, Metal-Oxide-Semiconductor (MOS) capacitor, metal fringe capacitor, trench capacitor, junction capacitor, and/or any other types of decoupling capacitor.

In some examples, the M1 track 121 and the M0 track 103 form two terminals of a decoupling capacitor. In these examples, the M1 track 121 is connected to a positive polarity VDD of a power supply of the IC, and M0 track 103 is connected to a negative polarity VSS of the power supply. In this way, a decoupling capacitor is created between VDD and VSS with the M1 track 121 and the M0 track 103 as the two terminals of the capacitor. Since the M1 track 121 is electrically connected to the M0 track 104 through a VIA0 via, a decoupling capacitor is also created between the M0 track 103 and the M0 track 104. In the same way, a decoupling capacitor between VDD and VSS may be created using the M1 track 121 and the M0 track 105, the M1 track 120 and the M0 track 104, the M1 track 122 and the M0 track 104, and/or any other pairs of metal layer tracks.

In some examples, the two terminals of the decoupling capacitor created by the DCAP cell 100 are connected to VDD and VSS to reduce noise and disturbance in the power supply. In one example, the voltage level of VDD drops due to a system disturbance, and the decoupling capacitor provides adequate power to the IC to maintain the voltage level of VDD. In another example, the voltage level of VDD increases due to a system disturbance, and the decoupling capacitor prevents excess current from flowing through the IC by keeping the voltage level of VDD stable.

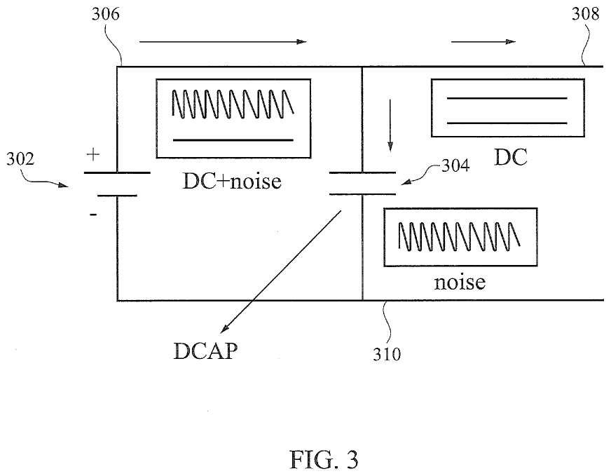

FIG. 3 illustrates an exemplary scenario schematic of a decoupling capacitor created by the DCAP cell 100. As can be seen, the positive polarity of a power supply 302 is connected to one terminal of a decoupling capacitor 304 at node 306, and the negative polarity of the power supply 302 is connected to the other terminal of the decoupling capacitor 304 at node 310. When the power supply 302 is affected by noise and system disturbance, the voltage at the positive polarity of the power supply 302 becomes noisy at the node 306. The decoupling capacitor 304 is used to eliminate the noise at the node 306 by providing a low impedance path for the noise from the node 306 to the node 310 and blocking DC signal from the node 306 to the node 310. In this way, a noise-free clean DC signal is provided at node 308.

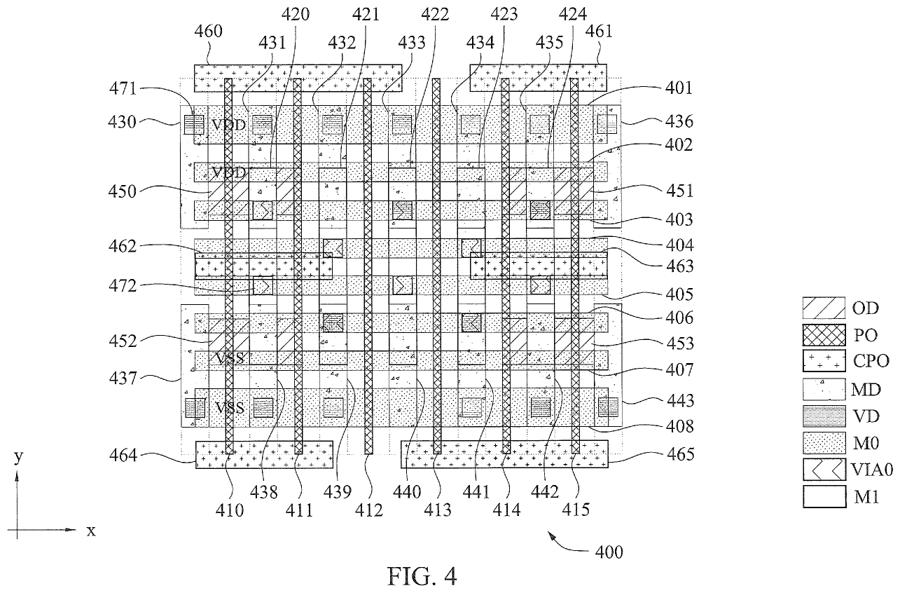

FIG. 4 illustrates another embodiment of the DCAP cell 400 in accordance with the present disclosure. In this embodiment, the DCAP cell 400 is rectilinearly shaped and is six (6) poly pitches wide laterally in the x-axis. In some embodiments, multiple DCAP cells 100 may be coupled either in the x-axis or the y-axis dimension to allow for greater complex functions to be realized. The coupling of the DCAP cells 400 may require additional connections in the metal layers (e.g. M1 or M2). The DCAP cell 400 may include M0 tracks 401-408, running on an M0 mask layer in the x-axis direction. The M0 tracks 401 and 402 may be configured to have a shared power line (VDD), and the M0 tracks 407 and 408 may be configured to have a shared ground (VSS).

In this embodiment, the DCAP cell 400 includes PO shapes 410-415 running orthogonal to the M0 shapes in the y-axis direction, M1 tracks 420-424 running on an M1 mask layer in the y-axis, MD shapes 430-443 running on an MD mask layer in the y-axis, OD shapes 450-453 running on an OD mask layer in the y-axis. VD vias 471 provide a means to connect MD layer to M0 layer, and VIA0 vias 472 provide a means to connect M0 layer to M1 layer. In some examples, the DCAP cell 400 includes CPO shapes 460-465 running on a CPO layer in the x-axis. The CPO shapes at the same horizontal level are disconnected to provide an isolation of the CPO shapes. For example, the CPO shape pairs 460 and 461, 462 and 463, 464 and 465, respectively, are disconnected from each other with an empty space between the two shapes.

In some embodiments, the M1 track 420 and the M0 track 404 form two terminals of a decoupling capacitor. The M1 track 420 may be connected to a positive polarity VDD of the power supply of the IC, and M0 track 404 may be connected to a negative polarity VSS of the power supply. In this way, a decoupling capacitor is created between VDD and VSS with the M1 track 420 and the M0 track 404 as the two terminals of the decoupling capacitor. Since the M1 track 420 is electrically connected to the M0 track 405 through a VIA0 via as shown, a decoupling capacitor is also created between the M0 track 404 and the M0 track 405. In the same way, a decoupling capacitor between VDD and VSS may be created using the following pairs of metal tracks: the M1 track 420 and the M1 track 421, the M1 track 421 and the M0 track 403, the M1 track 421 and the M0 track 405, the M1 track 421 and the M1 track 422, the M1 track 422 and the M0 track 404, the M1 track 422 and the M1 track 423, the M1 track 423 and the M0 track 403, the M1 track 423 and the M0 track 405, the M1 track 423 and the M1 track 424, the M1 track 424 and the M0 track 404, the M0 track 403 and the M0 track 404, the M0 track 404 and the M0 track 405.

The two terminals of the decoupling capacitors created by the DCAP cell 400 may be connected to VDD and VGG to reduce noise and disturbance in the power supply. In one example, the voltage level of VDD drops due to a system disturbance, and the decoupling capacitors provide adequate power to the IC to maintain the voltage level of VDD. In another example, the voltage level of VDD increases due to a system disturbance, and the decoupling capacitors prevent excess current from flowing through the IC by keeping the voltage level of VDD stable.

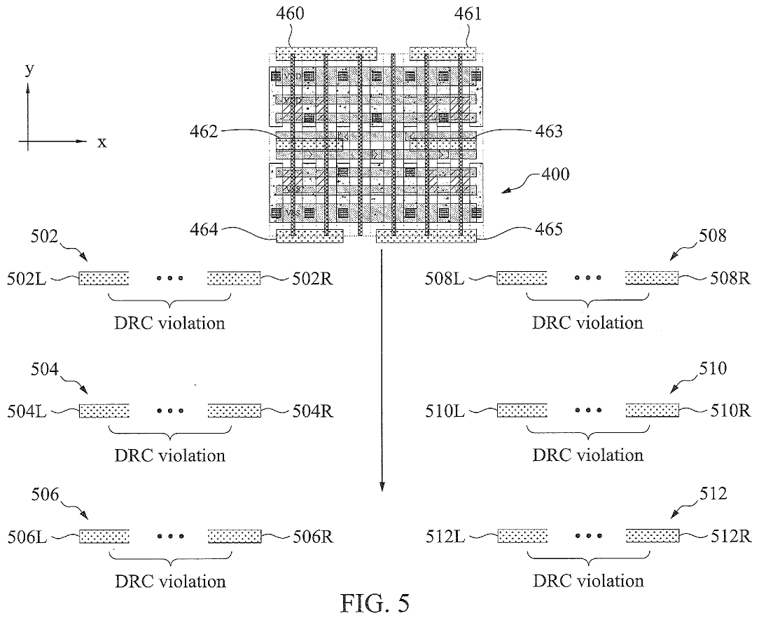

FIG. 5 illustrates another exemplary scenario of the DCAP cell 400 used for solving DRC violations. In this exemplary scenario, each of the six CPO lines 502, 504, 506, 508, 510 and 512 has a length greater than the first predetermined value for CPO lines, thus resulting in DRC violations. In this example, the distance between the right edge 502R of the CPO line 502 and the left edge 508L of the CPO line 508 is less than six (6) poly pitches and greater than four (4) poly pitches, and the CPO lines 502 and 508 are at the same horizontal level in the y-axis. The distance between the right edge 504R of the CPO line 504 and the left edge 510L of the CPO line 510 is less than six (6) poly pitches and greater than four (4) poly pitches, and the CPO lines 504 and 510 are at the same horizontal level in the y-axis. The distance between the right edge 506R of the CPO line 506 and the left edge 512L of the CPO line 512 is less than six (6) poly pitches and greater than four (4) poly pitches, and the CPO lines 506 and 512 are at the same horizontal level in the y-axis. In another embodiment, a DCAP cell 400 of a width m can be used to solve DRC violation of two CPO lines at a same horizontal level in the y-axis, wherein the distance between the right edge of the left CPO line and the left edge of the right CPO line is less than m and greater than n (m>n). The CPO lines 502, 504 and 506 are in parallel and horizontally arranged. The vertical distance between the CPO lines 502 and 504 is equal to the vertical distance between the CPO lines 460 and 462 in the DCAP cell 400, and the vertical distance between the CPO lines 504 and 506 is equal to the vertical distance between the CPO lines 462 and 464 in the DCAP cell 100.

In some embodiments, the DRC rules may specify an action to make the two edges of a CPO line as floating nodes to solve DRC violations. The DCAP cell 400 may be then placed by connecting the left edge of the CPO line 460 to the right edge 502R of the CPO line 502, the left edge of the CPO line 462 to the right edge 504R of the CPO line 504, the left edge of the CPO line 464 to the right edge 506R of the CPO line 506, the right edge of the CPO line 461 to the left edge 508L of the CPO line 508, the right edge of the CPO line 463 to the left edge 510L of the CPO line 510, and the right edge of the CPO line 465 to the left edge 512L of the CPO line 512. In this way, the right edges 502R, 504R and 506R of the CPO lines 502, 504, and 506 become floating nodes since the right edges of the CPO lines 460, 462 and 464 are disconnected from the left edges of the CPO lines 461, 463 and 465, and the left edges 508L, 510L and 512L of the CPO lines 508, 510, and 512 become floating nodes since the left edges of the CPO lines 461, 463 and 465 are disconnected from the right edges of the CPO lines 460, 462 and 464. In the same way, a second DCAP cell 400 (not shown) may be placed at the left edges 502L, 504L and 506L of the CPO lines 502, 504 and 506, and a third DCAP cell 400 (not shown) may be placed at the right edges 508R, 510R and 512R of the CPO lines 508, 510 and 512 to solve DRC violation. In some examples, multiple DCAP cells 400 may be placed along either the x-axis or the y-axis to solve DRC violations.

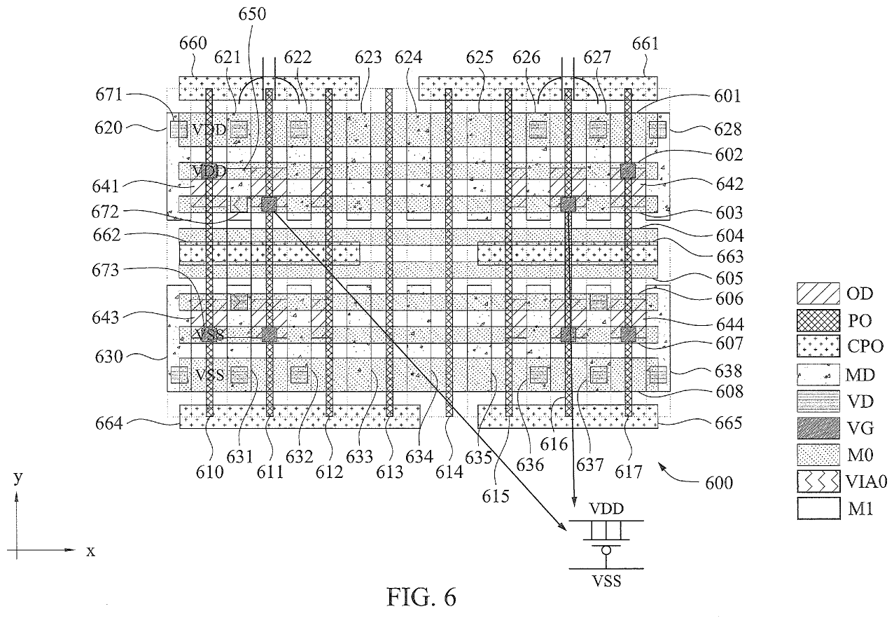

FIG. 6 illustrates still another embodiment of the DCAP cell 600 in accordance with the present disclosure. In this embodiment, the DCAP cell 600 is rectilinearly shaped and is eight (8) poly pitches wide laterally in the x-axis. In some embodiments, multiple DCAP cells 600 may be coupled either in the x-axis or the y-axis dimension to allow for greater complex functions to be realized. The coupling of the DCAP cells 600 may require additional connections in the metal layers (e.g. M1 or M2). The DCAP cell 600 may include M0 tracks 601-608, running on an M0 mask layer in the x-axis direction. The M0 tracks 601 and 602 may be configured to have a shared power line (VDD), and the M0 tracks 607 and 608 may be configured to have a shared ground (VSS).

In this embodiment, the DCAP cell 600 includes PO shapes 610-617 running orthogonal to the M0 shapes in the y-axis direction, MD shapes 620-628 and 630-638 running on an MD mask layer in the y-axis, OD shapes 641-644 running on an OD mask layer in the y-axis, and M1 track 650 running on an M1 mask layer in the y-axis. VD vias 671 provide a means to connect MD layer to M0 layer, VIA0 vias 672 provide a means to connect M0 layer to M1 layer, and VG vias 673 provide a means to connect PO layer to M0 layer. In some examples, the DCAP cell 600 includes CPO shapes 660-665 running on a CPO layer in the x-axis. The CPO shapes at the same y-axis level are disconnected to make the CPO shapes as floating nodes. For example, the CPO shape pairs 660 and 661, 662 and 663, 664 and 665 are disconnected from each other with an empty space between the two shapes.

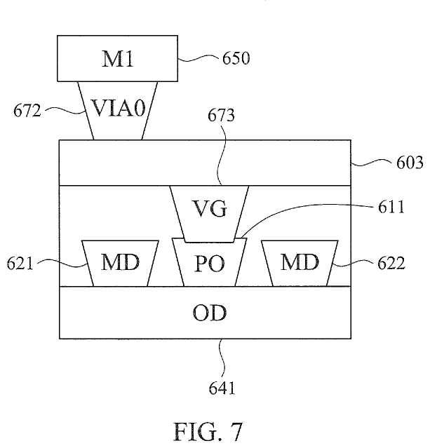

In some embodiments, a PMOS transistor is formed by the OD shape 641 serving as active area such as source, drain and bulk, and the PO shape 611 serving as gate electrode. In one example, the source, drain and bulk of the PMOS transistor are connected and used as a first terminal of a decoupling capacitor, and the gate of the PMOS transistor is used as a second terminal of the decoupling capacitor. A cross section of the PMOS transistor created by the OD shape 641, the PO shape 611, and/or other components is illustrated in FIG. 7. As can be seen, the PO shape 611 serves as the gate electrode of the PMOS transistor, and the active area of the PMOS transistor is formed by the OD shape 641. In one example, the PO shape 611 is electrically connected to the M0 track 603 through the VG via 673, and the M0 track 603 is electrically connected to the M1 track 650 through the VIA0 via 672. In this way, voltage values can be applied to the M1 track 650 to control voltage of the gate of the PMOS transistor. In another example, the M1 track 650 is connected to a positive polarity VDD of the power supply of the IC, and the OD shape 641 is connected to a negative polarity VSS of the power supply. In this way, a decoupling capacitor is created between VDD and VSS with the M1 track 650 and the OD shape 641 as the two terminals of the decoupling capacitor.

Referring back to FIG. 6, the M1 track 650 is electrically connected to the M0 track 603 through a VIA0 via, and the M0 track 603 is electrically connected to the PO shape 616 as shown. In this way, a decoupling capacitor is also created between the PO shape 616 and the OD shape 642 wherein the PO shape 616 serves as the gate electrode of a PMOS transistor, and the OD shape 642 serves as the active area of the PMOS transistor. In the same way, a decoupling capacitor between VDD and VSS may be created using the following pairs of shapes: the PO shape 610 and the OD shape 641, the PO shape 617 and the OD shape 642, the PO shape 610 and the OD shape 643, the PO shape 611 and the OD shape 643, the PO shape 616 and the OD shape 644, the PO shape 617 and the OD shape 644.

The two terminals of the decoupling capacitors created by the DCAP cell 600 may be connected to VDD and VSS to reduce noise and disturbance in the power supply. In one example, the voltage level of VDD drops due to a system disturbance, and the decoupling capacitors provide adequate power to the IC to maintain the voltage level of VDD. In another example, the voltage level of VDD increases due to a system disturbance, and the decoupling capacitors prevent excess current from flowing through the IC by keeping the voltage level of VDD stable. An exemplary advantage of using the decoupling capacitor created by the PMOS transistor in FIG. 6 is that creation of the decoupling capacitor using PMOS materials does not need any materials from M0 and M1 layers. Thus, valuable M0 and M1 layer resources can be saved for place and route with PMOS-based decoupling capacitors.

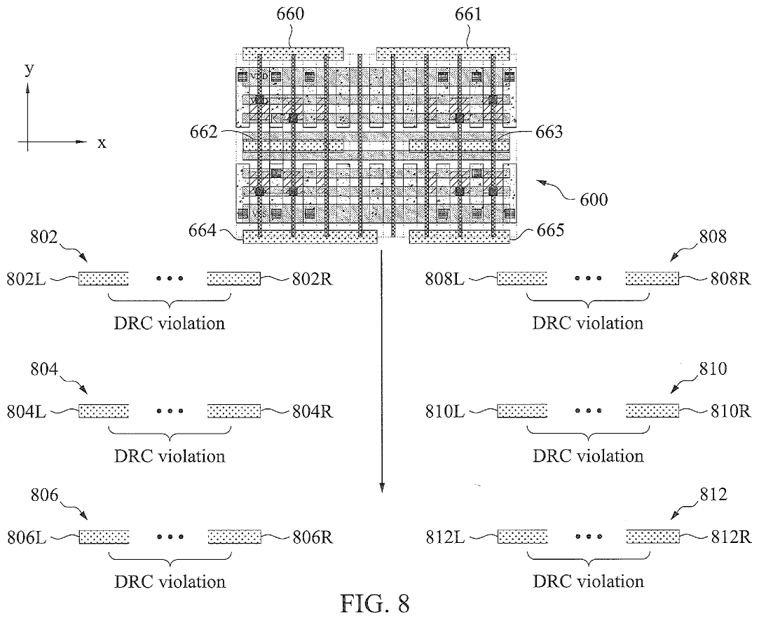

FIG. 8 illustrates still another exemplary scenario of the DCAP cell 600 used for solving DRC violations. In this exemplary scenario, each of the six CPO lines 802, 804, 806, 808, 810 and 812 has a length greater than the first predetermined value for CPO lines, thus resulting in DRC violations. In this example, the distance between the right edge 802R of the CPO line 802 and the left edge 808L of the CPO line 808 is less than eight (8) poly pitches and greater than six (6) poly pitches, and the CPO lines 802 and 808 are at the same horizontal level in the y-axis. The distance between the right edge 804R of the CPO line 804 and the left edge 810L of the CPO line 810 is less than eight (8) poly pitches and greater than six (6) poly pitches, and the CPO lines 804 and 810 are at the same horizontal level in the y-axis. The distance between the right edge 806R of the CPO line 806 and the left edge 812L of the CPO line 812 is less than eight (8) poly pitches and greater than six (6) poly pitches, and the CPO lines 806 and 812 are at the same horizontal level in the y-axis. In another embodiment, a DCAP cell 600 of a width m can be used to solve DRC violation of two CPO lines at a same horizontal level in the y-axis, wherein the distance between the right edge of the left CPO line and the left edge of the right CPO line is less than m and greater than n (m>n). The CPO lines 802, 804 and 806 are in parallel and horizontally arranged. The vertical distance between the CPO lines 802 and 804 is equal to the vertical distance between the CPO lines 660 and 662 in the DCAP cell 600, and the vertical distance between the CPO lines 804 and 806 is equal to the vertical distance between the CPO lines 662 and 664 in the DCAP cell 600.

In some embodiments, the DRC rules may specify an action to make the two edges of a CPO line as floating nodes to solve DRC violations. The DCAP cell 600 may be then placed by connecting the left edge of the CPO line 660 to the right edge 802R of the CPO line 802, the left edge of the CPO line 662 to the right edge 804R of the CPO line 804, the left edge of the CPO line 664 to the right edge 806R of the CPO line 806, the right edge of the CPO line 661 to the left edge 808L of the CPO line 808, the right edge of the CPO line 663 to the left edge 810L of the CPO line 810, and the right edge of the CPO line 665 to the left edge 812L of the CPO line 812. In this way, the right edges 802R, 804R and 806R of the CPO lines 802, 804 and 806 become floating nodes since the right edges of the CPO lines 660, 662 and 664 are disconnected from the left edges of the CPO lines 661, 663 and 665, and the left edges 808L, 810L and 812L of the CPO lines 808, 810 and 812 become floating nodes since the left edges of the CPO lines 661, 663 and 665 are disconnected from the right edges of the CPO lines 660, 662 and 664. In the same way, a second DCAP cell 600 (not shown) may be placed at the left edges 802L, 804L and 806L of the CPO lines 802, 804 and 806, and a third DCAP cell 600 (not shown) may be placed at the right edges 808R, 810R and 812R of the CPO lines 808, 810 and 812 to solve DRC violation. In some examples, multiple DCAP cells 600 may be placed along either the x-axis or the y-axis to solve DRC violations.

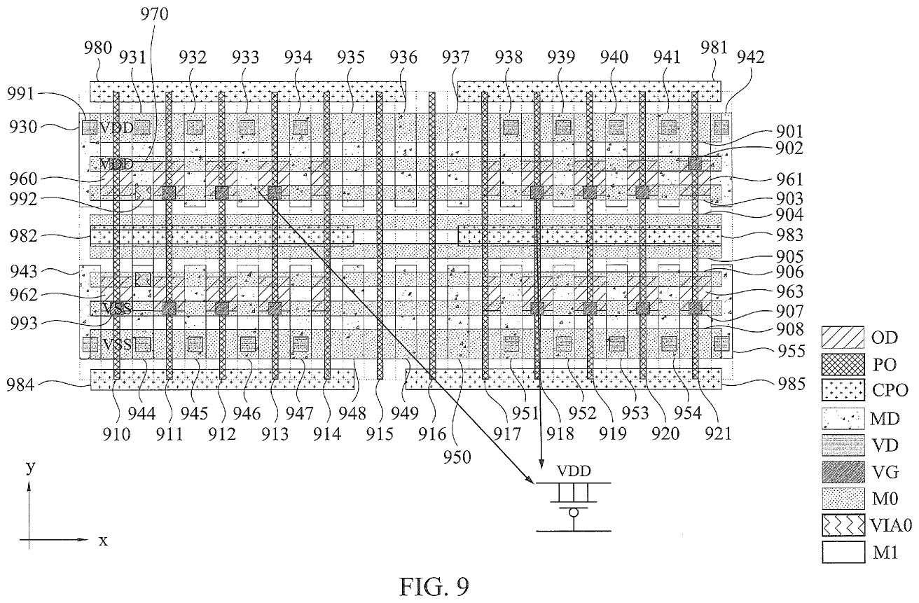

FIG. 9 illustrates yet another embodiment of the DCAP cell 900 in accordance with the present disclosure. In this embodiment, the DCAP cell 900 is rectilinearly shaped and is twelve (12) poly pitches wide laterally in the x-axis. In some embodiments, multiple DCAP cells 900 may be coupled either in the x-axis or the y-axis dimension to allow for greater complex functions to be realized. The coupling of the DCAP cells 900 may require additional connections in the metal layers (e.g. M1 or M2). The DCAP cell 900 may include M0 tracks 901-908, running on an M0 mask layer in the x-axis direction.

In some embodiments, the DCAP cell 900 includes PO shapes 910-921 running orthogonal to the M0 shapes in the y-axis direction, MD shapes 930-955 running on an MD mask layer in the y-axis, OD shapes 960-963 running on an OD mask layer in the y-axis, and M1 track 970 running on an M1 mask layer in the y-axis. VD vias 991 provide a means to connect MD layer to M0 layer, VIA0 vias 992 provide a means to connect M0 layer to M1 layer, and VG vias 993 provide a means to connect PO layer to M0 layer. In some examples, the DCAP cell 900 includes CPO shapes 980-985 running on a CPO layer in the x-axis. The CPO shapes at the same y-axis level are disconnected to make the CPO shapes as floating nodes. For example, the CPO shape pairs 980 and 981, 982 and 983, 984 and 985 are disconnected from each other with an empty space between the two shapes.

In some embodiments, a first PMOS transistor is formed by the OD shape 960 serving as an active area such as source, drain and bulk, and the PO shape 912 serving as gate electrode. In one example, the source, the drain and the bulk of the first PMOS transistor are connected and used as a first terminal of a decoupling capacitor, and the gate of the first PMOS transistor is used as a second terminal of the decoupling capacitor.

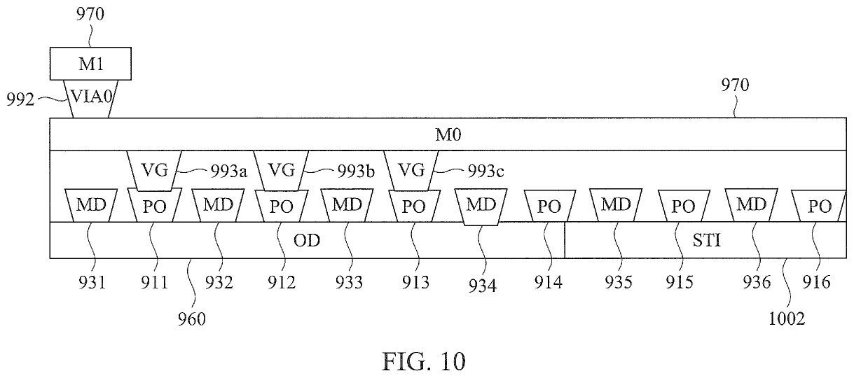

A cross section of the first PMOS transistor created by the OD shape 960, the PO shape 912, and/or other components is illustrated in FIG. 10. As can be seen, the PO shape 912 serves as the gate electrode of the first PMOS transistor, and the active area of the first PMOS transistor is formed by the OD shape 960. In this way, the decoupling capacitor is formed between the PO shape 912 and the OD shape 960. In some examples, the PO shape 911 and the OD shape 960 form a second PMOS transistor, and the PO shape 913 and the OD shape 960 form a third PMOS transistor. Thus a second and a third decoupling capacitors are formed between the PO shape 911 and the OD shape 960, and the PO shape 913 and the OD shape 960. The formed PMOS transistors may be electrically isolated from other parts of the DCAP cell 900 by a shallow trench isolation (STI) shape 1002.

In one example, the PO shapes 911, 912 and 913 are electrically connected to the M0 track 903 through three vias VG 993a-993c, and the M0 track 903 is electrically connected to the M1 track 970 through a via VIA0 992. In this way, voltage values can be applied to the M1 track 970 to control voltage of the gates of the first, second, third PMOS transistors. In another example, the M1 track 970 is connected to a positive polarity VDD of the power supply of the IC, and the OD shape 960 is connected to a negative polarity VSS of the power supply. In this way, a decoupling capacitor is created between VDD and VSS with the M1 track 970 and the OD shape 960 as the two terminals of the capacitor.

Referring back to FIG. 9, the M1 track 970 is electrically connected to the M0 track 903 through a via VIA0 992, and the M0 track 903 is electrically connected to the PO shape 918 as shown. In this way, a decoupling capacitor is also created between the PO shape 918 and the OD shape 961 wherein the PO shape 918 serves as the gate electrode of a fourth PMOS transistor, and the OD shape 961 serves as the active area of the fourth PMOS transistor. In the same way, a decoupling capacitor between VDD and VGG may be created using the following pairs of shapes: the PO shape 919 and the OD shape 961, the PO shape 920 and the OD shape 961, the PO shape 921 and the OD shape 961, the PO shape 910 and the OD shape 962, the PO shape 911 and the OD shape 962, the PO shape 912 and the OD shape 962, the PO shape 913 and the OD shape 962, the PO shape 918 and the OD shape 963, the PO shape 919 and the OD shape 963, the PO shape 920 and the OD shape 963, the PO shape 921 and the OD shape 963.

The two terminals of the decoupling capacitors created by the DCAP cell 900 may be connected to VDD and VGG to reduce noise and disturbance in the power supply. In one example, the voltage level of VDD drops due to a system disturbance, and the decoupling capacitors provide adequate power to the IC to maintain the voltage level of VDD. In another example, the voltage level of VDD increases due to a system disturbance, and the decoupling capacitors prevent excess current from flowing through the IC by keeping the voltage level of VDD stable.

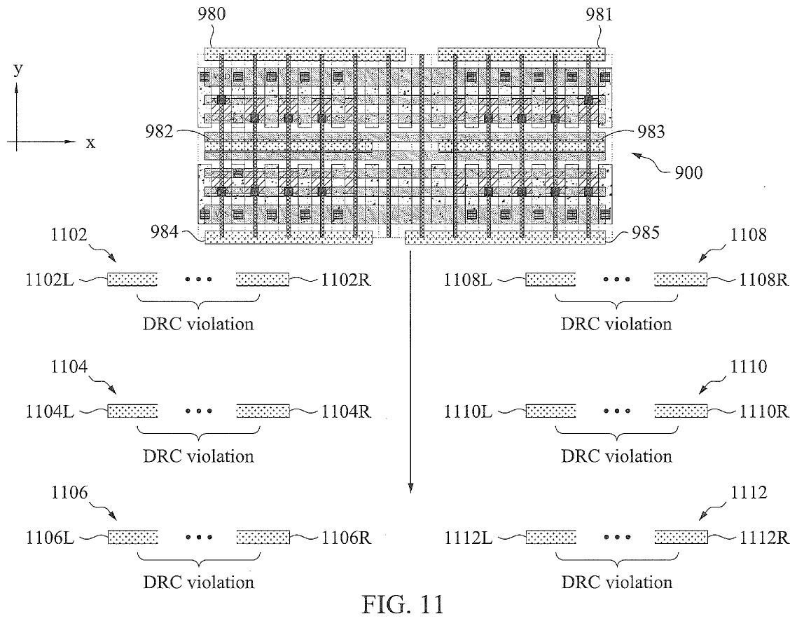

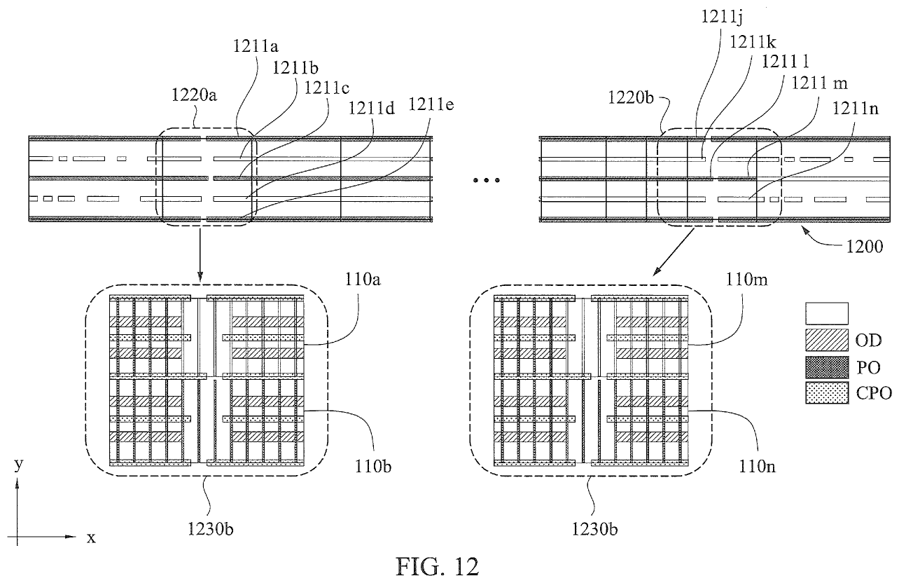

FIG. 11 illustrates still another exemplary scenario of the DCAP cell 900 used for solving DRC violations. In this exemplary scenario, each of the six CPO lines 1102, 1104, 1106, 1108, 1110 and 1112 has a length greater than the first predetermined value for CPO lines, thus resulting in DRC violations. In this example, the distance between the right edge 1102R of the CPO line 1102 and the left edge 1108L of the CPO line 1108 is less than twelve (12) poly pitches and greater than eight (8) poly pitches, and the CPO lines 1102 and 1108 are at the same horizontal level in the y-axis. The distance between the right edge 1104R of the CPO line 1104 and the left edge 1110L of the CPO line 1110 is less than twelve (12) poly pitches and greater than eight (8) poly pitches, and the CPO lines 1104 and 1110 are at the same horizontal level in the y-axis. The distance between the right edge 1106R of the CPO line 1106 and the left edge 1112L of the CPO line 1112 is less than twelve (12) poly pitches and greater than eight (8) poly pitches, and the CPO lines 1106 and 1112 are at the same horizontal level in the y-axis. In another embodiment, a DCAP cell 900 of a width m can be used to solve DRC violation of two CPO lines at a same horizontal level in the y-axis, wherein the distance between the right edge of the left CPU line and the left edge of the right CPO line is less than m and greater than n (m>n). The CPO lines 1102, 1104 and 1106 are in parallel and horizontally arranged. The vertical distance between the CPO lines 1102 and 1104 is equal to the vertical distance between the CPO lines 980 and 982 in the DCAP cell 900, and the vertical distance between the CPO lines 1104 and 1106 is equal to the vertical distance between the CPO lines 982 and 984 in the DCAP cell 900.

In some embodiments, the DRC rules may specify an action to make the two edges of a CPO line as floating nodes to solve DRC violations. The DCAP cell 900 may be then placed by connecting the left edge of the CPO line 980 to the right edge 1102R of the CPO line 1102, the left edge of the CPO line 982 to the right edge 1104R of the CPO line 1104, the left edge of the CPO line 984 to the right edge 1106R of the CPO line 1106, the right edge of the CPO line 981 to the left edge 1108L of the CPO line 1108, the right edge of the CPO line 983 to the left edge 1110L of the CPO line 1110, and the right edge of the CPO line 985 to the left edge 1112L of the CPO line 1112. In this way, the right edges 1102R, 1104R and 1106R of the CPO lines 1102, 1104 and 1106 become floating nodes since the right edges of the CPO lines 980, 982 and 984 are disconnected from the left edges of the CPO lines 981, 983 and 985, and the left edges 1108L, 1110L and 1112L of the CPO lines 1108, 1110 and 1112 become floating nodes since the left edges of the CPO lines 981, 983 and 985 are disconnected from the right edges of the CPO lines 980, 982 and 984. In the same way, a second DCAP cell 900 (not shown) may be placed at the left edges 1102L, 1104L and 1106L of the CPO lines 1102, 1104 and 1106, and a third DCAP cell 900 (not shown) may be placed at the right edges 1108R, 1110R and 1112R of the CPO lines 1108 1110, and 1112 to solve DRC violation. In some examples, multiple DCAP cells 900 may be placed along either the x-axis or y-axis to solve DRC violations.

FIG. 12 illustrates still another exemplary scenario for using any of the DCAP cells discussed above for solving DRC violations. In this exemplary scenario, DRC is performed based on a design rule data set for a layout 1200 of an IC to detect one or more DRC violations at one or more locations on the layout 1200. In some embodiments, the one or more locations comprise one or more CPO lines 1211a to 1211n with a length greater than the first predetermined value, thus resulting in DRC violations. Examples of the first predetermined value include 1 μm, 2 μm, 3 μm, and/or any other values.

In one example, the CPO lines 1211a to 1211n are horizontally arranged, and the vertical distance between two horizontally adjacent CPO lines in the CPO lines 1211a to 1211n is equal to the vertical distance between two horizontally adjacent CPO lines in one or more DCAP cells 110a to 110n, as shown. The one or more DCAP cells 110a to 110n are placed at the one or more locations on the layout 1200 such that the one or more DRC violations at the one or more locations are solved by the one or more DCAP cells 110a to 110n.

In some embodiments, a space 1220a comprises a plurality of locations with DRC violations. The width in the x-axis of the space 1220a is less than twelve (12) poly pitches and greater than eight (8) poly pitches, and the height in the y-axis of the space 1220a is equal to the height of two DCAP cells 100 with a width of twelve (12) poly pitches. Two DCAP cells 100a and 100b with a width of twelve (12) poly pitches may be vertically stacked to form a DCAP group 1230a, and the DCAP group 1230a may be manually placed at the space 1220a to solve the DRC violations at the plurality of locations in the space 1220a. Manual placement of an IC layout component may be referred to manual operations of choosing and positioning layout geometric shapes by an IC layout engineer using layout design tool without any automation process. In some other embodiments, a space 1220b comprises a plurality of locations with DRC violations. The width in the x-axis of the space 1220b is less than twelve (12) poly pitches and greater than eight (8) poly pitches, and the height in the y-axis of the space 1220b is equal to the height of two DCAP cells 100 with a width of twelve (12) poly pitches. Two DCAP cells 100m and 100n with a width of twelve (12) poly pitches may be vertically stacked to form a DCAP group 1230b, and the DCAP group 1230b may be placed at the space 1220b to solve the DRC violations at the plurality of locations in the space 1220b.

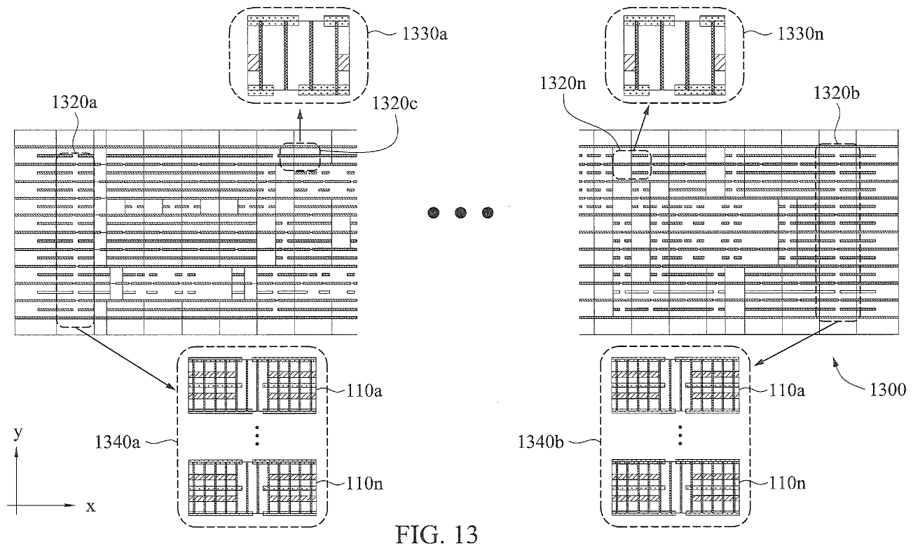

FIG. 13 illustrates still another exemplary scenario for using any of the DCAP cells discussed above for solving DRC violations. In this exemplary scenario, DRC is performed based on a design rule data set for a layout 1300 of an IC to detect one or more DRC violations at one or more locations on the layout 1300. In some embodiments, vertically or horizontally adjacent locations with DRC violations may be groups to form one or more spaces 1320a-1320n as shown. The widths in the x-axis of the one or more spaces 1320a-1320n may be 4 μm, 6 μm, 8 μm, 12 μm, and/or any other values.

In some embodiments, one or more fill cells 1330a to 1330n may be placed at the one or more spaces 1320a-1320n to solve the one or more DRC violations. A fill cell 1330 may be referred to a layout cell used to solve DRC violations and to fill gaps in an IC layout. In today's Very Large Scale Integration (VLSI) chip designs, pattern density and uniformity are critical. As such, any “empty” regions of an IC are generally filled with generic fill cells for pattern density. The fill (sometimes also referred to as filler) cells attempt to match patterns associated with the FEOL and some MEOL. These fill cells rarely have any specific function ascribed to them other than pattern matching.

To further provide decoupling capacitor functions and save M0/M1 layer resources, some of the one or more fill cells 1330a to 1330n may be replaced by one or more DCAP cells 100 based on the following criteria: a fill cell 1330 is replaced by a DCAP cell 100 with the same width and height if the decoupling capacitor formed by the DCAP cell 100 does not include materials from M0/M1 layers. In this way, the decoupling capacitors formed by the one or more DCAP cells 100 do not include any materials from M0/M1 layers, and the M0/M1 layer resources are saved for other layout activities such as placement and routing of the IC. In some embodiments, DCAP cells 100 with a width equal to or greater than eight (8) poly pitches comprise decoupling capacitors formed by a PMOS transistors, and DCAP cells 100 with a width less than eight (8) poly pitches comprise decoupling capacitors formed by M0/M1 layers.

In some examples, based on a budget of M0/M1 layer resources on the layout, some of the one or more fill cells 1330a to 1330n may be replaced by the one or more DCAP cells 100 comprising decoupling capacitors formed by M0/M1 layer. In one example, a total available area of M0/M1 layer on the layout of an IC is A0/A1, and a minimum area of M0/M1 layer reserved for placement, routing, and/or other layout activities is B0/B1. Thus, a total area of M0/M1 layer that can be used for creating decoupling capacitors by the DCAP cells 100 is calculated as A0−B0/A1−B1. In another example, one or more DCAP cells 100a to 100n with a width of twelve (12) poly pitches are vertically stacked to form a DCAP group 1340a, and one or more DCAP cells 100a′ to 100n′ with a width of twelve (12) poly pitches are vertically stacked to form a DCAP group 1340b. The DCAP groups 1340a and 1340b may be placed at the space 1220b to solve the DRC violations at the plurality of locations in the spaces 1320a and 1320b.

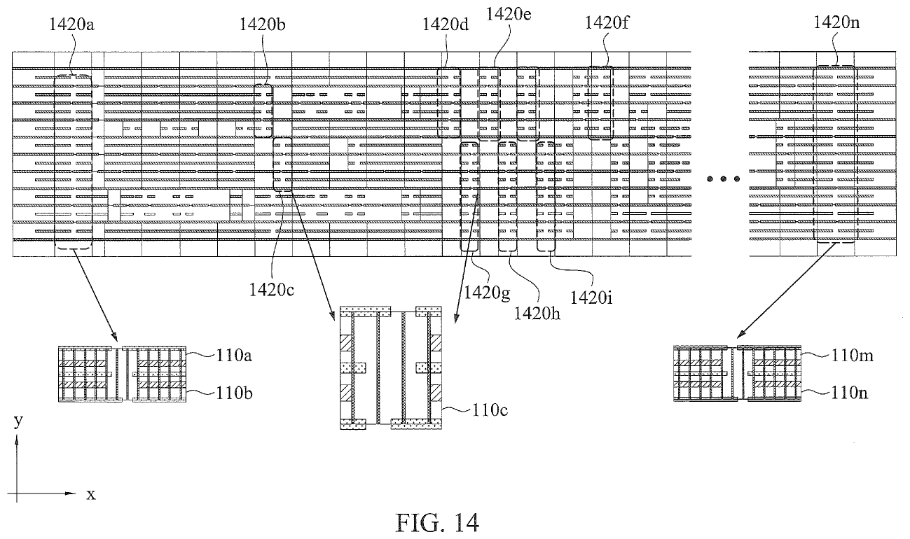

FIG. 14 illustrates still another exemplary scenario for using any of the DCAP cells discussed above for solving DRC violations, in accordance with an exemplary embodiment of the present disclosure. In this exemplary scenario, DRC is performed based on a design rule data set for a layout 1400 of an IC to detect one or more DRC violations at one or more locations on the layout 1400. In some embodiments, vertically or horizontally adjacent locations with DRC violations may be groups to form one or more spaces 1420a-1420n as shown. The widths in the x-axis of the one or more spaces 1420a-1420n may be 4 μm, 6 μm, 8 μm, 12 μm, and/or any other values.

In some embodiments, one or more fill cells may be placed at the one or more spaces 1420a-1420n to solve the one or more DRC violations. Based on the budget of M0 and M1 layer resources on the layout, some of the one or more fill cells may be replaced by one or more DCAP cells 100 or 400 comprising decoupling capacitors formed by the M0 and M1 layers. In one example, the total available areas of M0 and M1 layers on the layout of an IC are A0 and A1, respectively, and the minimum areas of M0 and M1 layers reserved for placement, routing, and other layout activities are B0 and B1, respectively. Thus, the total areas of M0 and M1 layers that can be used for creating decoupling capacitors by the DCAP cells 100 or 400 are calculated as A0-B0 and A1−B1, respectively. In another example, the total areas of M0 and M1 layers needed for creating decoupling capacitors in the one or more DCAP cells 100 or 400 are C0 and C1, respectively, where C0<=A0−B0 and C1<=A1−B1. In this case, all the one or more fill cells are replaced by the one or more DCAP cells 100 or 400.

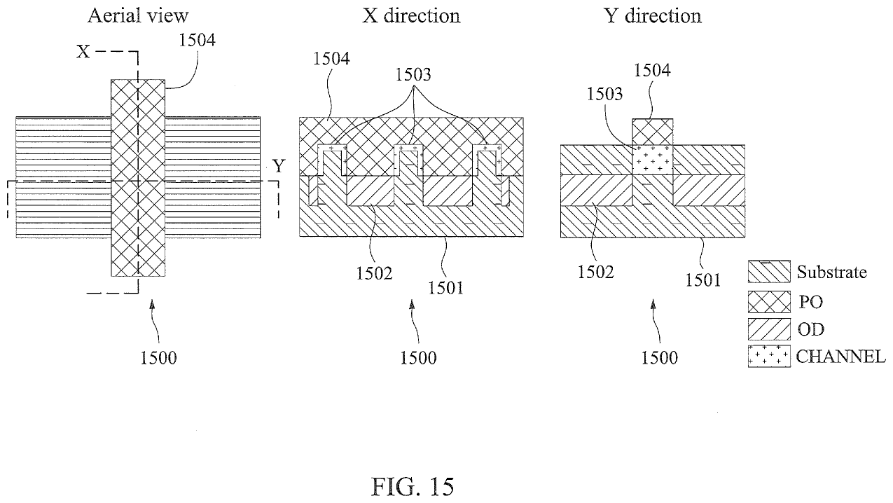

FIG. 15 illustrates an exemplary transistor 1500 in the DCAP cell 600 or 900 used for creating the decoupling capacitor, in accordance with an exemplary embodiment of the present disclosure. In some embodiments, the transistor 1500 comprises a substrate 1501, an OD shape 1502 serving as active area of the transistor 1500 such as source, drain and bulk, a PO shape 1504 serving as gate electrode, one or more channels 1503, and/or any other components (e.g., an insulation layer). In one example, the source, the drain and the bulk (not shown) in the OD shape 1502 of the transistor 1500 are connected and used as a first terminal of a decoupling capacitor, and the PO shape 1504 is used as a second terminal of the decoupling capacitor. In another example, the transistor 1500 is a fin field-effect transistor (FinFET) with gate placed on at least two sides of the channel 1503 to form a multi-gate structure.

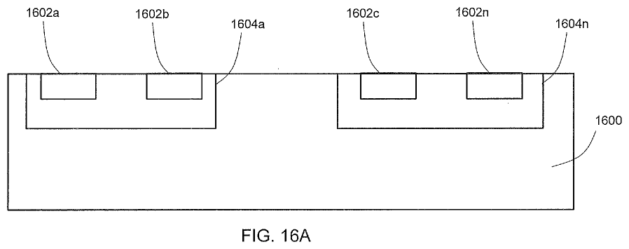

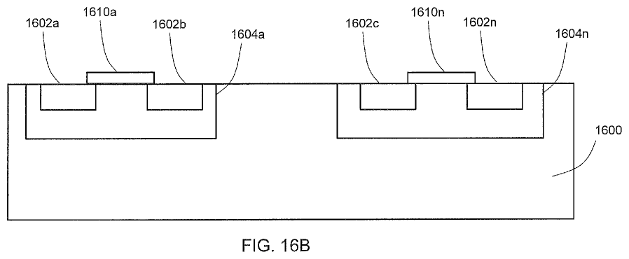

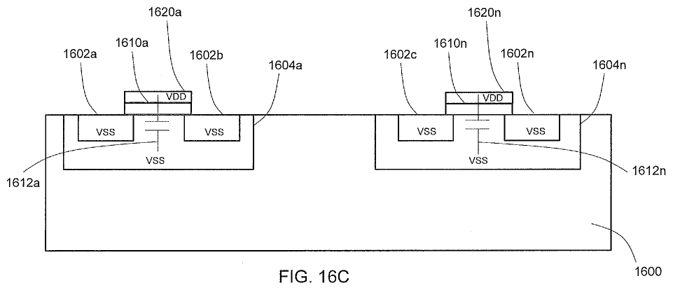

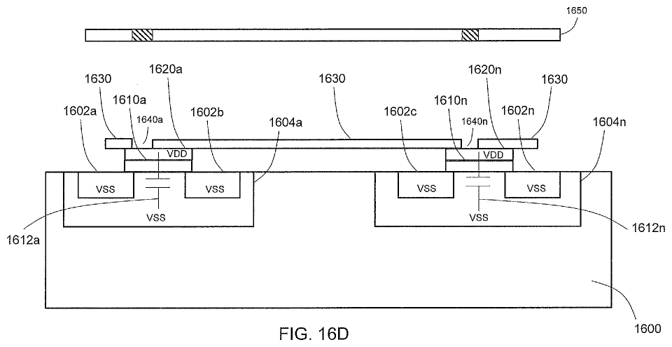

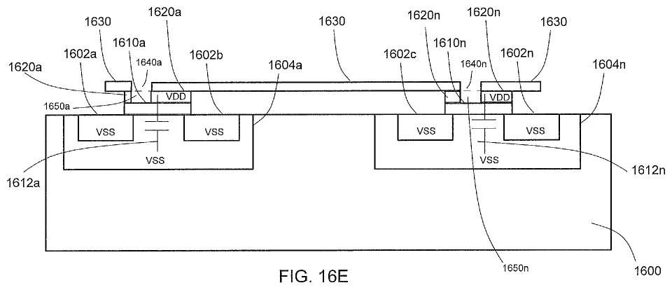

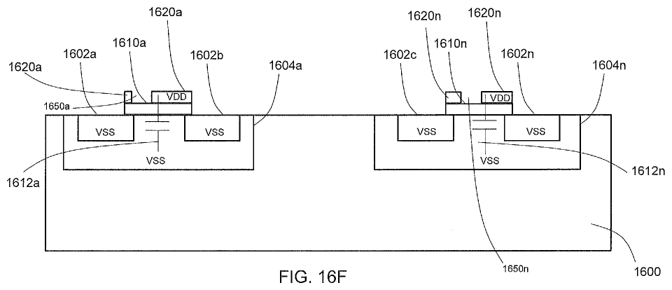

FIG. 16A-F schematically depicts sequential steps of a method for forming a process-friendly DCAP cell, according to an embodiment of the present disclosure. FIG. 16A illustrates a cross-sectional side view of an OD region 1600 for one or more process-friendly DCAP cells according to an embodiment of the present disclosure. In some embodiments, the OD region 1600 comprises one or more active areas for one or more transistors. Examples of one or more active areas include p-type substrate, n-type well, n-type substrate, n-type region, p-type region for creating different transistor components such as source, drain and bulk. In one example, the OD region 1600 comprises one or more p-type regions 1602a-n used as sources or drains for one or more PMOS transistors, and one or more n-well regions 1604a-n used as bulks for the one or more PMOS transistors.

FIG. 16B illustrates a cross-sectional side view of one or more insulating layers 1610a-n deposited on the OD region 1600, according to an embodiment of the present disclosure. In some embodiments, the one or more insulating layers 1610a-n comprise a silicon dioxide (SiO₂) layer grown on the surface of the OD region 1600 covering areas between sources and drains of the one or more PMOS transistors.

FIG. 16C illustrates a cross-sectional side view of one or more PO layers 1620a-n deposited on the one or more insulating layers 1610a-n, according to an embodiment of the present disclosure. In some embodiments, the one or more PO layers 1620a-n are used as the gates for the one or more PMOS transistors. In one example, the source, drain and bulk of each of the one or more PMOS transistors are connected to a ground VSS through one or more metal layers (not shown) and used as a first terminal of one or more decoupling capacitors 1612a-n. In another example, the gate of each of the one or more PMOS transistors is connected to a VDD through one or more metal layers (not shown) and used as a second terminal of the one or more decoupling capacitors 1612a-n.

FIG. 16D illustrates a cross-sectional side view of a photoresist layer 1630 deposited on the one or more PO layers 1620a-n, according to an embodiment of the present disclosure. In some embodiments, the photoresist layer 1630 comprises one or more photoresist layer openings 1640a-n formed by a cut mask 1650. The one or more photoresist layer openings 1640a-n may correspond to the one or more CPO lines shown in various embodiments in FIGS. 1, 4, 6 and 9. In one example, the one or more photoresist layer openings 1640a-n are formed to solve one or more DRC violations as illustrated in various embodiments in FIGS. 2, 5, 8, and 11-14.

FIG. 16E illustrates a cross-sectional side view of one or more PO layer openings 1650a-n formed by an etching process, according to an embodiment of the present disclosure. In one example, the one or more PO layers 1620a-n are selectively etched in the etching process according to the one or more photoresist layer openings 1640a-n to form the one or more PO layer openings 1650a-n. In another example, the areas of the one or more PO layers 1620a-n vertically below the one or more photoresist layer openings 1640a-n are etched, resulting in different PO pieces separated by the one or more PO layer openings 1650a-n. In still another example, the one or more PO layer openings 1650a-n are formed according to a predetermined layout pattern of an integrated circuit.

FIG. 16F illustrates a cross-sectional side view of the photoresist layer 1630 being removed from the one or more process-friendly DCAP cells, according to an embodiment of the present disclosure. In some embodiments, the photoresist layer 1630 is removed so that the gate, source, drain and bulk of each of the one or more PMOS transistors can be accessed by external circuitry.

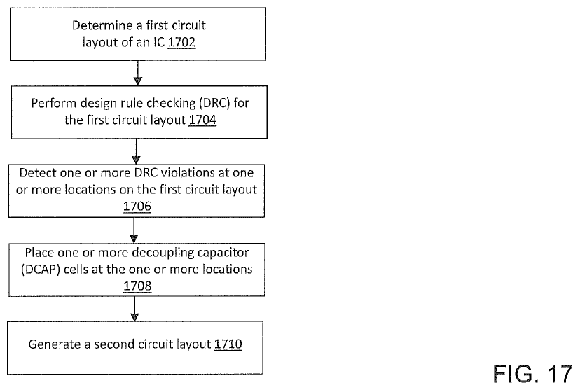

FIG. 17 illustrates an example method 1700 for designing an IC. The operations of method 1700 presented below are intended to be illustrative. In some embodiments, method 1700 may be accomplished with one or more additional operations not described and/or without one or more of the operations discussed. Additionally, the order in which the operations of method 1700 are illustrated in FIG. 17 and described below is not intended to be limiting.

At step 1702, a first circuit layout of an IC is determined. In some embodiments, the first circuit layout is automatically generated by an electronic design automation (EDA) tool to represent the IC, and the first layout comprises planar geometric shapes corresponding to the patterns of metal, oxide, or semiconductor layers that make up the components of the IC.

At step 1704, a design rule checking (DRC) is performed for the first circuit layout. In some embodiments, the DRC verifies whether the first circuit layout meets one or more geometric constraints imposed on the IC layout for a particular process technology.

At step 1706, one or more DRC violations are detected at one or more locations on the first circuit layout. In one example, the DRC violation comprises a layout shape of a particular layer with a width larger than the maximum width allowed by the DRC rules for a process technology. In another example, the DRC violation comprises a space between two adjacent objects less than the minimum space allowed by the DRC rules for the process technology.

At step 1708, one or more decoupling capacitor (DCAP) cells are placed at the one or more locations to solve the one or more DRC violations. In one example, the one or more DCAP cells comprise one or more decoupling capacitors formed by M0 and M1 layers. In another example, the one or more DCAP cells comprise one or more decoupling capacitors formed by one or more p-channel metal-oxide semiconductor (PMOS) transistors.

At step 1710, a second circuit layout is generated after the one or more DCAP cells are placed to solve the one or more DRC violations.

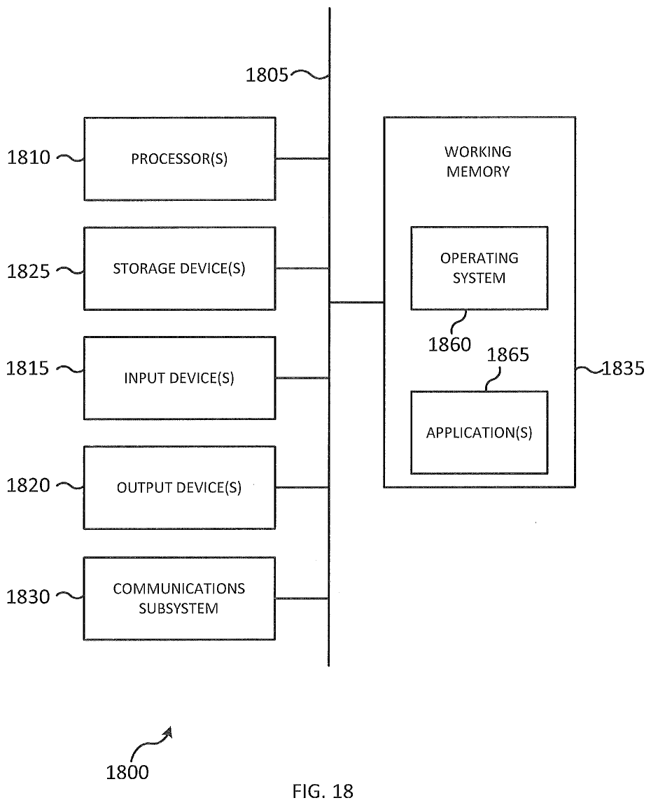

FIG. 18 illustrates a simplified computer system that can be used to implement various embodiments described and illustrated herein. A computer system 1800 as illustrated in FIG. 18 may be incorporated into devices such as a portable electronic device, mobile phone, or other device as described herein. FIG. 18 provides a schematic illustration of one embodiment of a computer system 1800 that can perform some or all of the steps of the methods provided by various embodiments. It should be noted that FIG. 18 is meant only to provide a generalized illustration of various components, any or all of which may be utilized as appropriate. FIG. 18, therefore, broadly illustrates how individual system elements may be implemented in a relatively separated or relatively more integrated manner.

The computer system 1800 is shown comprising hardware elements that can be electrically coupled via a bus 1805, or may otherwise be in communication, as appropriate. The hardware elements may include one or more processors 1810, including without limitation one or more general-purpose processors and/or one or more special-purpose processors such as digital signal processing chips, graphics acceleration processors, and/or the like; one or more input devices 1815, which can include without limitation a mouse, a keyboard, a camera, and/or the like; and one or more output devices 1820, which can include without limitation a display device, a printer, and/or the like.

The computer system 1800 may further include and/or be in communication with one or more non-transitory storage devices 1825, which can comprise, without limitation, local and/or network accessible storage, and/or can include, without limitation, a disk drive, a drive array, an optical storage device, a solid-state storage device, such as a random access memory (“RAM”), and/or a read-only memory (“ROM”), which can be programmable, flash-updateable, and/or the like. Such storage devices may be configured to implement any appropriate data stores, including without limitation, various file systems, database structures, and/or the like.

The computer system 1800 might also include a communications subsystem 1830, which can include without limitation a modem, a network card (wireless or wired), an infrared communication device, a wireless communication device, and/or a chipset such as a Bluetooth™ device, an 1002.11 device, a WiFi device, a WiMax device, cellular communication facilities, etc., and/or the like. The communications subsystem 1830 may include one or more input and/or output communication interfaces to permit data to be exchanged with a network such as the network described below to name one example, other computer systems, television, and/or any other devices described herein. Depending on the desired functionality and/or other implementation concerns, a portable electronic device or similar device may communicate image and/or other information via the communications subsystem 1830. In other embodiments, a portable electronic device, e.g. the first electronic device, may be incorporated into the computer system 1800, e.g., an electronic device as an input device 1815. In some embodiments, the computer system 1800 will further comprise a working memory 1835, which can include a RAM or ROM device, as described above.

The computer system 1800 also can include software elements, shown as being currently located within the working memory 1835, including an operating system 1860, device drivers, executable libraries, and/or other code, which may comprise computer programs provided by various embodiments, and/or may be designed to implement methods, and/or configure systems, provided by other embodiments, as described herein. Merely by way of example, one or more procedures described with respect to the methods discussed above, such as those described in relation to FIGS. 2, 5, 8, 11-14 and 17, might be implemented as code and/or instructions executable by a computer and/or a processor within a computer; in an aspect, then, such code and/or instructions can be used to configure and/or adapt a general purpose computer or other device to perform one or more operations in accordance with the described methods.

A set of these instructions and/or code may be stored on a non-transitory computer-readable storage medium, such as the storage device(s) 1825 described above. In some cases, the storage medium might be incorporated within a computer system, such as computer system 1800. In other embodiments, the storage medium might be separate from a computer system e.g., a removable medium, such as a compact disc, and/or provided in an installation package, such that the storage medium can be used to program, configure, and/or adapt a general purpose computer with the instructions/code stored thereon. These instructions might take the form of executable code, which is executable by the computer system 1800 and/or might take the form of source and/or installable code, which, upon compilation and/or installation on the computer system 1800 e.g., using any of a variety of generally available compilers, installation programs, compression/decompression utilities, etc., then takes the form of executable code.

It will be apparent to those skilled in the art that substantial variations may be made in accordance with specific requirements. For example, customized hardware might also be used, and/or particular elements might be implemented in hardware, software including portable software, such as applets, etc., or both. Further, connection to other computing devices such as network input/output devices may be employed.

As mentioned above, in one aspect, some embodiments may employ a computer system such as the computer system 1800 to perform methods in accordance with various embodiments of the technology. According to a set of embodiments, some or all of the procedures of such methods are performed by the computer system 1800 in response to processor 1810 executing one or more sequences of one or more instructions, which might be incorporated into the operating system 1860 and/or other code contained in the working memory 1835. Such instructions may be read into the working memory 1835 from another computer-readable medium, such as one or more of the storage device(s) 1825. Merely by way of example, execution of the sequences of instructions contained in the working memory 1835 might cause the processor(s) 1810 to perform one or more procedures of the methods described herein. Additionally or alternatively, portions of the methods described herein may be executed through specialized hardware.

The terms “machine-readable medium” and “computer-readable medium,” as used herein, refer to any medium that participates in providing data that causes a machine to operate in a specific fashion. In an embodiment implemented using the computer system 1800, various computer-readable media might be involved in providing instructions/code to processor(s) 1810 for execution and/or might be used to store and/or carry such instructions/code. In many implementations, a computer-readable medium is a physical and/or tangible storage medium. Such a medium may take the form of a non-volatile media or volatile media. Non-volatile media include, for example, optical and/or magnetic disks, such as the storage device(s) 1825. Volatile media include, without limitation, dynamic memory, such as the working memory 1835.

Common forms of physical and/or tangible computer-readable media include, for example, a floppy disk, a flexible disk, hard disk, magnetic tape, or any other magnetic medium, a CD-ROM, any other optical medium, punch cards, paper tape, any other physical medium with patterns of holes, a RAM, a PROM, EPROM, a FLASH-EPROM, any other memory chip or cartridge, or any other medium from which a computer can read instructions and/or code.

Various forms of computer-readable media may be involved in carrying one or more sequences of one or more instructions to the processor(s) 1810 for execution. Merely by way of example, the instructions may initially be carried on a magnetic disk and/or optical disc of a remote computer. A remote computer might load the instructions into its dynamic memory and send the instructions as signals over a transmission medium to be received and/or executed by the computer system 1800.

The communications subsystem 1830 and/or components thereof generally will receive signals, and the bus 1805 then might carry the signals and/or the data, instructions, etc. carried by the signals to the working memory 1835, from which the processor(s) 1810 retrieves and executes the instructions. The instructions received by the working memory 1835 may optionally be stored on a non-transitory storage device 1825 either before or after execution by the processor(s) 1810.

In accordance with some embodiments, a method for making an integrated circuit (IC), includes: forming one or more decoupling capacitor (DCAP) cells, wherein each of the one or more DCAP cells includes one or more polysilicon (PO) layers; depositing a photoresist layer above the one or more PO layers, wherein the photoresist layer includes one or more photoresist layer openings formed by a cut mask, wherein the one or more photoresist layer openings are formed to solve one or more DRC violations; forming one or more PO layer openings in the one or more PO layers based on the one or more photoresist layer openings; and removing the photoresist layer. In some embodiments, forming the one or more PO layer openings is performed by an etching process. In further embodiments, the one or more PO layer openings are formed according to a predetermined layout pattern of the IC. In some embodiments, the one or more DCAP cells are four (4) poly pitches, six (6) poly pitches, eight (8) poly pitches, or twelve (12) poly pitches wide along an x-axis direction. In further embodiments, the one or more DCAP cells further include: at least one first capacitor formed by an M0 metal layer and an M1 metal layer, and at least one second capacitor formed by at least one p-channel metal oxide semiconductor (PMOS) transistor. In some embodiments, the method further includes: connecting a first terminal of the at least one first capacitor to a positive polarity of a power supply of the IC, and a second terminal of the at least one first capacitor to a negative polarity of the power supply; and connecting a first terminal of the at least one second capacitor to the positive polarity of the power supply, and a second terminal of the at least one second capacitor to the negative polarity of the power supply. In some embodiments, the one or more photoresist layer openings are formed to solve the one or more DRC violations by manually placing the one or more DCAP cells at one or more locations of the one or more DRC violations. In further embodiments, the one or more photoresist layer openings are formed to solve the one or more DRC violations by: placing one or more fill cells at one or more locations of the one or more DRC violations to solve the one or more DRC violations, and replacing the one or more fill cells by the one or more DCAP cells of same sizes. In further embodiments, the one or more photoresist layer openings are formed to solve the one or more DRC violations by replacing the one or more fill cells by the one or more DCAP cells of the same sizes if widths along an x-axis direction of the one or more fill cells are greater than or equal to a predetermined threshold value. In some embodiments, the at least one PMOS transistor is a fin field-effect transistor (FinFET).

In accordance with further embodiments, a semiconductor manufacturing system includes: at least one apparatus configured to: form one or more decoupling capacitor (DCAP) cells in an integrated circuit (IC), wherein each of the one or more DCAP cells includes one or more polysilicon (PO) layers; deposit a photoresist layer above the one or more PO layers, wherein the photoresist layer includes one or more photoresist layer openings formed by a cut mask, wherein the one or more photoresist layer openings are formed to solve one or more design rule check (DRC) violations; form one or more PO layer openings in the one or more PO layers based on the one or more photoresist layer openings; and remove the photoresist layer. In some embodiments, the one or more DCAP cells further include at least one first capacitor formed by an M0 metal layer and an M1 metal layer. In further embodiments, the at least one apparatus is further configured to: connect a first terminal of the at least one first capacitor to a positive polarity of a power supply of the IC, and a second terminal of the at least one first capacitor to a negative polarity of the power supply. In some embodiments, the one or more DCAP cells include at least one second capacitor formed by at least one p-channel metal oxide semiconductor (PMOS) transistor, wherein the at least one PMOS transistor is a fin field-effect transistor (FinFET). Additionally, in some embodiments, the at least one apparatus is further configured to: connect a first terminal of the at least one second capacitor to a positive polarity of a power supply, and a second terminal of the at least one second capacitor to a negative polarity of the power supply.

In alternative embodiments, an integrated circuit (IC) includes: one or more decoupling capacitor (DCAP) cells, wherein each of the one or more DCAP cells includes one or more polysilicon (PO) layers and at least one capacitor to decouple a power supply of the IC from a ground of the IC; and one or more PO layer openings formed in the one or more PO layers, wherein the one or more PO layer openings are formed based on one or more photoresist layer openings, wherein the one or more photoresist layer openings are formed in a photoresist layer by a cut mask, and the one or more photoresist layer openings are formed to solve one or more design rule check (DRC) violations. In some embodiments, the at least one capacitor is formed by a metal layer M0 and a metal layer M1 of the IC. In further embodiments, the at least one capacitor is formed by at least one p-channel metal oxide semiconductor (PMOS) transistor. In some embodiments, the at least one PMOS transistor is a fin field-effect transistor (FinFET). In further embodiments, the one or more DCAP cells are four (4) poly pitches, six (6) poly pitches, eight (8) poly pitches, or twelve (12) poly pitches wide along an x-axis direction.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the scope of the present disclosure, and that they may make various changes, substitutions, and alterations herein without departing from the scope of the present disclosure.

What is claimed is:

1. A method for making an integrated circuit (IC), comprising:
forming one or more decoupling capacitor (DCAP) cells, wherein each of the one or more DCAP cells comprises one or more polysilicon (PO) layers;
depositing a photoresist layer above the one or more PO layers, wherein the photoresist layer comprises one or more photoresist layer openings formed by a cut mask;
forming one or more PO layer openings in the one or more PO layers based on the one or more photoresist layer openings; and
removing the photoresist layer.

2. The method of claim 1, wherein forming the one or more PO layer openings is performed by an etching process.

3. The method of claim 1, wherein the one or more PO layer openings are formed according to a predetermined layout pattern of the IC.

4. The method of claim 1, wherein the one or more DCAP cells are four (4) poly pitches, six (6) poly pitches, eight (8) poly pitches, or twelve (12) poly pitches wide along an x-axis direction.

5. The method of claim 1, wherein the one or more DCAP cells further comprise:
at least one first capacitor formed by an M0 metal layer and an M1 metal layer; and
at least one second capacitor formed by at least one p-channel metal oxide semiconductor (PMOS) transistor.

6. The method of claim 5, further comprising:
connecting a first terminal of the at least one first capacitor to a positive polarity of a power supply of the IC, and a second terminal of the at least one first capacitor to a negative polarity of the power supply; and
connecting a first terminal of the at least one second capacitor to the positive polarity of the power supply, and a second terminal of the at least one second capacitor to the negative polarity of the power supply.

7. The method of claim 1, wherein the one or more photoresist layer openings are formed to solve the one or more DRC violations by manually placing the one or more DCAP cells at one or more locations of the one or more DRC violations.

8. The method of claim 1, wherein the one or more photoresist layer openings are formed to solve the one or more DRC violations by:
placing one or more fill cells at one or more locations of the one or more DRC violations to solve the one or more DRC violations; and
replacing the one or more fill cells by the one or more DCAP cells of same sizes.

9. The method of claim 8, wherein the one or more photoresist layer openings are formed to solve the one or more DRC violations by replacing the one or more fill cells by the one or more DCAP cells of the same sizes if widths along an x-axis direction of the one or more fill cells are greater than or equal to a predetermined threshold value.

10. The method of claim 5, wherein the at least one PMOS transistor is a fin field-effect transistor (FinFET).

11. A decoupling capacitor (DCAP) cell, comprising:
one or more polysilicon (PO) layers;
one or more PO layer openings formed in the one or more PO layers; and
at least one first capacitor.

12. The DCAP cell of claim 11, wherein the at least one first capacitor is formed by an M0 metal layer and an M1 metal layer.

13. The DCAP cell of claim 11, wherein the at least one first capacitor comprises:
a first terminal connected to a positive polarity of a power supply of an integrated circuit (IC); and
a second terminal connected to a negative polarity of the power supply of the IC.

14. The DCAP cell of claim 11, further comprising at least one second capacitor formed by at least one p-channel metal oxide semiconductor (PMOS) transistor, wherein the at least one PMOS transistor is a fin field-effect transistor (FinFET).

15. The DCAP cell of claim 14, wherein the at least one second capacitor comprises:
a first terminal connected to a positive polarity of a power supply of an integrated circuit (IC); and
a second terminal connected to a negative polarity of the power supply of the IC.

16. An integrated circuit (IC), comprising:
one or more decoupling capacitor (DCAP) cells, wherein each of the one or more DCAP cells comprises one or more polysilicon (PO) layers and at least one capacitor to decouple a power supply of the IC from a ground of the IC; and
one or more PO layer openings formed in the one or more PO layers.

17. The IC of claim 16, wherein the at least one capacitor is formed by a metal layer M0 and a metal layer M1 of the IC.

18. The IC of claim 16, wherein the at least one capacitor is formed by at least one p-channel metal oxide semiconductor (PMOS) transistor.

19. The IC of claim 18, wherein the at least one PMOS transistor is a fin field-effect transistor (FinFET).

20. The IC of claim 16, wherein the one or more DCAP cells are four (4) poly pitches, six (6) poly pitches, eight (8) poly pitches, or twelve (12) poly pitches wide along an x-axis direction.
